(19) United States
(12) Patent Application Publication
(10) Pub. No.: US 2007/0146832 A1
(43) Pub. Date: Jun. 28, 2007

(54) Electronic device assembly

(75) Inventor: Takaya Nakayama, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 11/529,385

(22) Filed: Sep. 29, 2006

(30) Foreign Application Priority Data
Dec. 22, 2005 (JP) 2005-369469

(51) Int. Cl. G03F 3/08

(52) U.S. Cl. 358/520

(57) ABSTRACT

A device unit, which mainly has, for example, wires, includes a main body portion having a primary function and a bracket portion functioning as an attachment part to a device. The main body portion and the bracket portion of the device unit are detachably combined with each other. In an assembly process, the device unit is attached to another device unit with the bracket portion through a side surface of the storage device. In order to detach the device unit from the device and to attach the device unit to the device when the device is set in a field, the main body portion is simply detached from and attached to the bracket portion through a front or rear surface of the device.

### BACKGROUND OF THE INVENTION

1. Field of the Invention

The present invention relates to a structure of a device having a single housing in which a plurality of units are housed and to assembly, maintenance, and replacement methods for the device.

2. Description of the Related Art

A device comprises a plurality of units. For example, a device is a storage device such as a RAID (Redundant Array of Independent Disks). A plurality of storage devices provided in a disk array system (high-capacity random-access memory system). Each unit has part of a function in the storage device. Each unit of the storage device is, for example, a disk enclosure unit, a controller unit, a power source unit, and a battery unit. The storage device is generally provided with a frame having a substantially rectangular prism shape. Each of the storage devices of the disk array system can generic provide a RAID system.

The disk array system is set and used in a field. In the field, the storage devices are assembled side by side together. With regards to processing of wires in such a storage device, each storage device that has the plurality of internally wired units disposed in a single frame and allows for the maintenance of the units only through the front and rear surfaces of the storage device.

Japanese Patent No. 2829172 discloses a method for housing cables in a space provided between a side surface of each unit of a device and a side surface of the frame. In this method, Japanese Patent No. 2829172, bus bar cables are inserted into the space between the side surface of each unit of the device and the side surface of the device frame and are drawn towards the front surface so as to be connected to the units of the device through the front surface of the device. In order to achieve this, as is apparent from the comparison of Japanese Patent No. 2829172, an additional space is provided adjacent to the side surface of each unit of the device. In the method disclosed in Japanese Patent No. 2829172, it is necessary to provide additional spaces on the sides of the devices, which leads to an increase in width of the storage devices.

On the other hand, as mentioned above, in a state of an array of the storage devices placed side by side, the attachment and detachment of the bus bar cables of the storage device excluding the storage devices disposed at the end of the array must be performed by pulling out the corresponding storage device in the array of the storage devices.

### SUMMARY OF THE INVENTION

Accordingly, the present invention provides an electronic device having a unit accessible through the front/rear surface of a frame of the device, without increasing the size of the electronic device. The unit is attachable to the electronic device frame. The unit comprises housing and a bracket. The housing comprises one or more connectors to connect with other units in the device frame and one or more engagers. The bracket comprises one or more first engagers engageable with the device frame, one or more second engagers engageable with the housing engagers, one or more openings overlap-able with the housing connectors and an attachment flange attachable to the device frame.

### BRIEF DESCRIPTION OF THE DRAWINGS

FIG. 1 illustrates the storage device 100 according to an embodiment of the present invention;

FIG. 2A illustrates a front view of the storage device 100 according to an embodiment of the present invention;

FIG. 2B illustrates a right side view of the storage device 100 according to an embodiment of the present invention;

FIG. 2C illustrates a rear side view of the storage device 100 according to an embodiment of the present invention;

FIG. 2D illustrates a left side view of the storage device 100 according to an embodiment of the present invention;

FIG. 3 illustrates a state where a plurality of the storage devices 100 are arranged side by side as a disk array system, according to an embodiment of the present invention;

FIG. 4 shows a partial overhead view of FIG. 1 of the bus bar unit 1 and the BU shelf 2 according to an embodiment of the present invention;

FIG. 5 shows the bracket 1b of the bus bar unit 1 in a partial overhead view of FIG. 4 according to an embodiment of the present invention;

FIG. 6 shows a projected figure of bracket 1b in three directions within a line A-A′ shown in FIG. 5, according to an embodiment of the present invention;

FIG. 7 shows cross-sectional views of main body 1a and bracket 1b of the bus bar unit in two directions according to an embodiment of the present invention;

FIG. 8 shows an assembly figure of the position of the bus bar unit 1 which is installed in BU shelf 2 according to an embodiment of the present invention;

FIG. 9 shows from the upper side view of the storage device 100 when main body 1a and bracket 1b of the bus bar unit 1 are combining or engaging according to an embodiment of the present invention;

FIG. 10 shows an assembling figure from the upper side of the storage device 100 where bus bar unit 1 is installed in BU shelf 2 according to an embodiment of the present invention;

FIG. 11 shows a assembly figure from two directions where bus bar unit 1 is installed in BU shelf 2, and correspond to the cross section taken along line A-A′ in FIG. 5 according to an embodiment of the present invention;

FIG. 12 shows an assembled figure from the upper side of device where bus bar unit 1 is installed in BU shelf 2 according to an embodiment of the present invention;

FIG. 13 shows an assembly figure from the rear side, the left side, and above where the main body 1a is uninstalled from the bracket 1b of the bus bar unit 1, according to an embodiment of the present invention;

FIG. 14 shows an assembly figure from the upper side of the storage device 100 where the main body 1a is uninstalled in the bracket 1b, that is, for the (−X) direction 102 according to an embodiment of the present invention;

### DESCRIPTION OF THE PREFERRED EMBODIMENTS

A plurality of directions is defined by the description below. The direction is used by all of the figures of this embodiment.

An X-direction 101 refers to a normal-line direction of front and rear surfaces of a storage device 100. The front and rear side of the storage device 100 are able to open when a disk array system lays the storage devices 100 side-by-side. An −X-direction 102 is an opposite direction of the X-direction 101.

A Y-direction 104 refers to a normal-line direction of left and right surfaces of the storage device 100. The front and rear side of the storage device 100 are not able to open when the disk array system lays the storage devices 100 side-by-side.

A Z-direction 102 refers to a normal-line direction of upper and lower surfaces of the storage device 100.

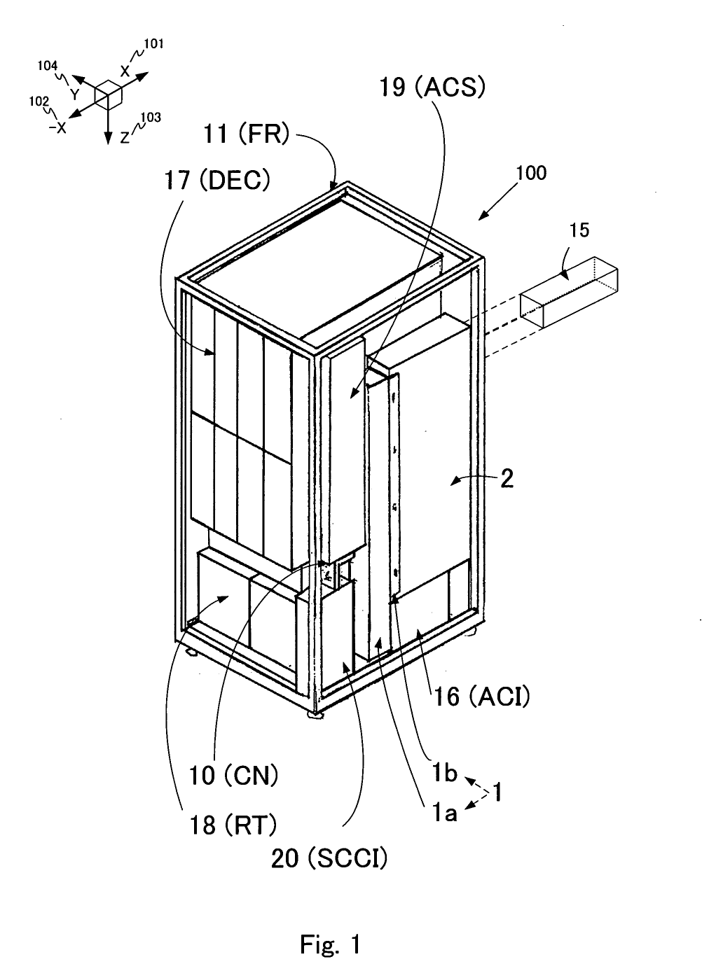

FIG. 1 illustrates one of the storage devices 100 in the disk array system (high-capacity random-access memory system) according to an embodiment of the present invention. The storage device 100 has a frame (FR) 11. For example, the FR 11 can be formed of metal and has a rectangular box shape. The FR 11 has a plurality of shelves. A plurality of units can be incorporated or provided on the shelf in the FR 11. For example, the units of the storage device 100 are a connector unit (CN) 10, an alternating current interface unit (ACI) 16, a disk enclosure controller (DEC) 17, a router (RT) 18, an alternating current section (ACS) 19, a system component control interface (SCCI) 20 according to an aspect of the embodiments, a bus bar unit 1 is provided. The bus bar unit 1 of the storage device 100 is divided into a housing 1a (main body portion 1a) and a bracket 1b. The housing is a main body 1a. The main body 1a separate from the bracket 1b in the −X direction 102. For example, the bus bar unit 1 can attach to a battery unit shelf (BU shelf) 2 of the storage device 100. The BU shelf 2 contains one or more battery units 15. One of the shelves in the FR 11 is the BU shelf 2. According to an aspect of the embodiments, the BU shelf 2 may be formed as part of the frame 11 and/or unit of the device in the frame 11 of the device.

Each of the units of the storage device 100 can be classified as two types by maintenance period. A first type of unit of the storage device 100 often needs maintenance. A second type of unit of the storage device 100 occasionally needs maintenance. The first type units are designed in a place exchanged easily in the storage device 100. The place can be back of a front cover in front of the storage device 100 or back of a rear cover in rear of the storage device 100 according to an embodiment of the present invention.

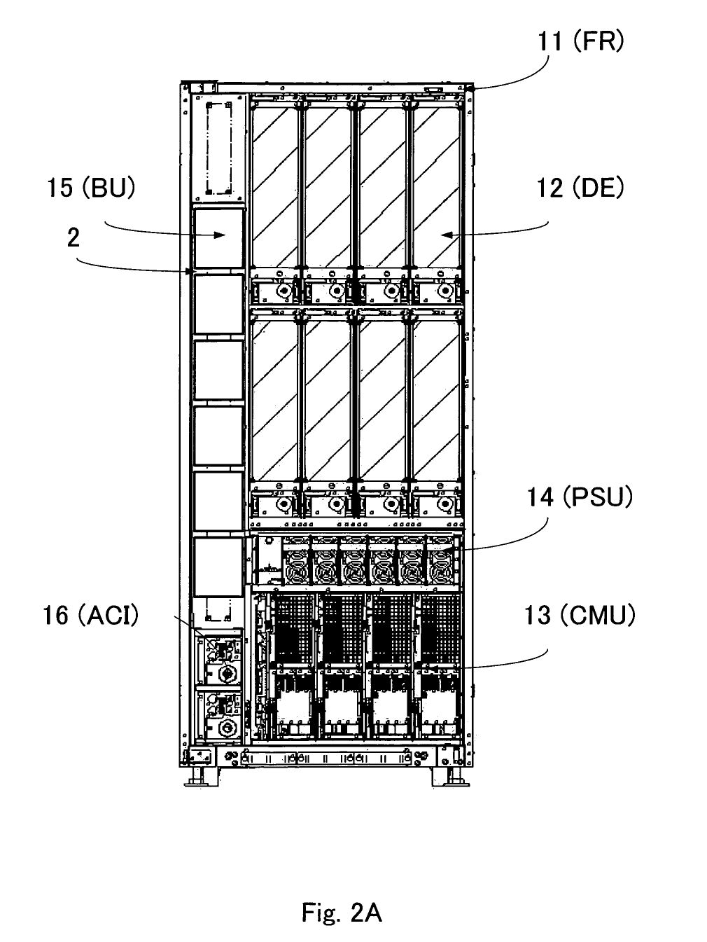

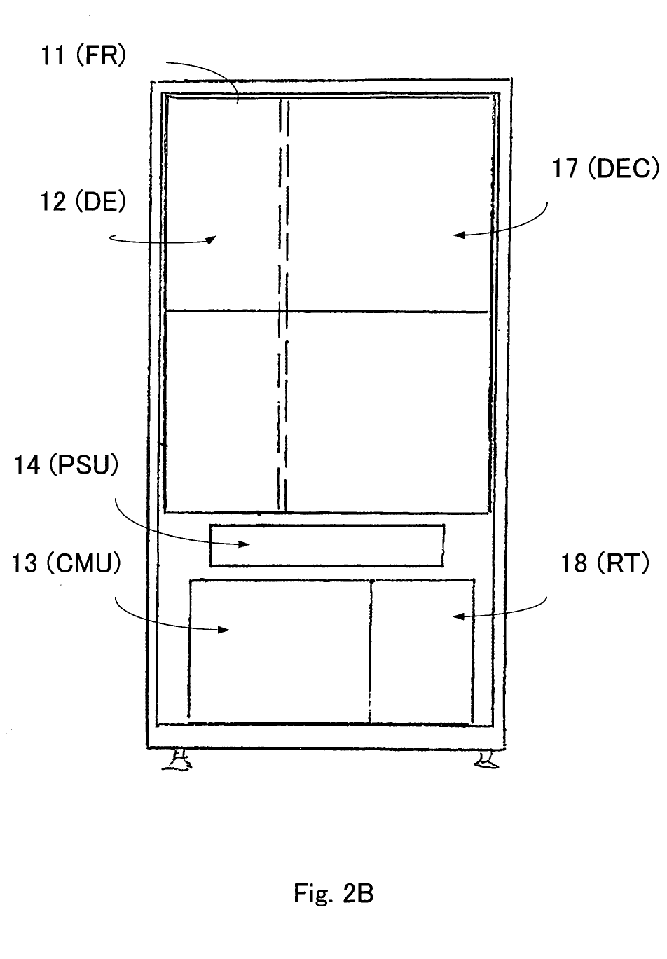

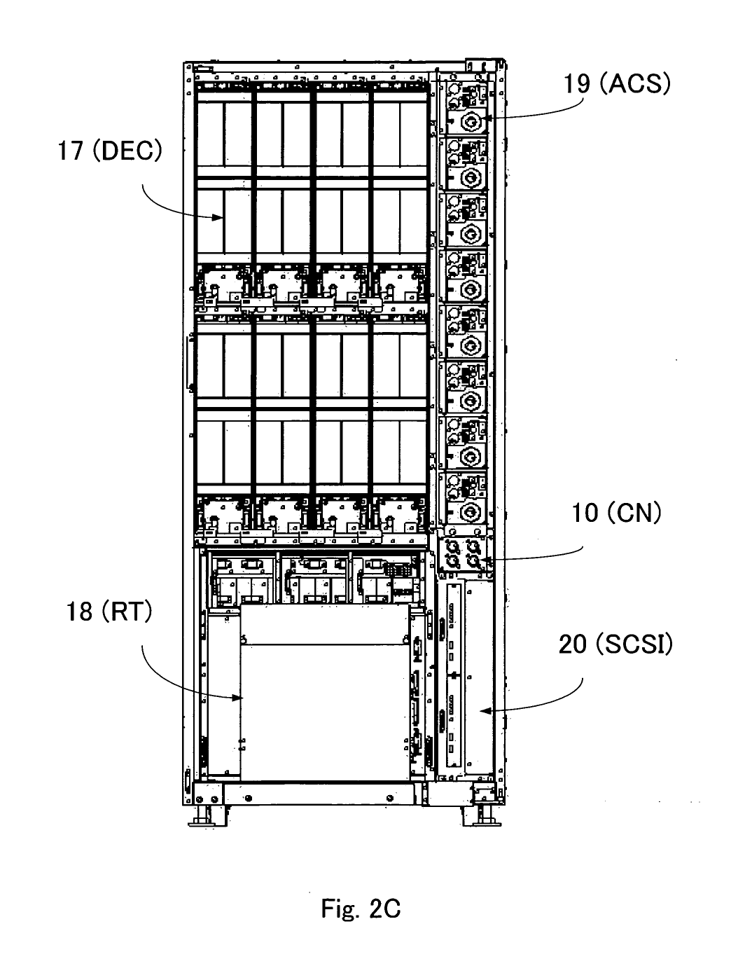

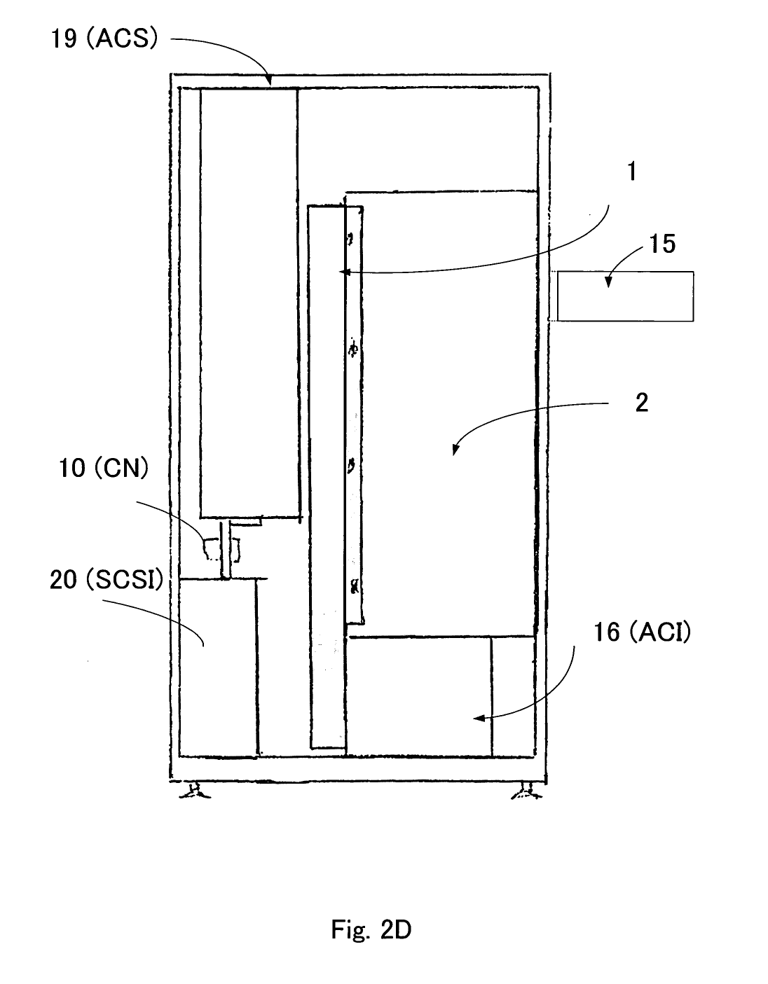

FIG. 2A illustrates a front view of the storage device 100. The first type units for setting up on the front side of the FR 11 are a disk enclosure unit (DE) 12, a controller module unit (CMU) 13, a power source unit (PSU) 14, a battery unit (BU) 15, and a An alternating current interface (ACI) 16. The DE 12 is an assembly of hard disk drives (HDD). The CMU 13 is a controller having a controlling function for the entire device 100 and an interface with respect to a server. The BU 15 is not only provided for supplying power, but also outputs various types of control signals that indicate the conditions of batteries. The BU15 is installed in the BU shelf 2. The PSU 14 provides the provided power source to the BU 15. The ACI 16 is an AC-power input for the CMU 13.

FIG. 2B illustrates a right side view of the storage device 100 according to an embodiment of the present invention. The first type units for setting up on the front or rear side of the FR 11 are the disk enclosure unit (DE) 12, a disk enclosure controller unit (DEC) 17, the controller module unit (CMU) 13, the power source unit (PSU) 14, a router (RT) 18. The DEC 17 includes controllers for disk enclosures included in the DE 12, and includes a power source for each DE 12. The RT 18 is a router for changing connections of the DEC 17.

FIG. 2C illustrates a rear side view of the storage device 100 according to an embodiment of the present invention. The first type units are set up on the rear side of the FR 11. The first type units are the disk enclosure controller (DEC) 17, the router (RT) 18, an alternating current section (ACS) 19, a system component control interface (SCCI) 20, and a connector (CN) 10.

The ACS 19 is an AC-power input for each DE 12. The SCCI 20 is a power-source linkage unit with respect to a server. The CN 10 connects a control signal and a power source of each of the units.

FIG. 2D illustrates a left side view of the storage device 100 according to an embodiment of the present invention. The First type of units set up on the front and rear side of the FR 11 are the ACS 19, the CN 10, the SCCI 20, the BU 15, and the ACI 16. The second type of units for setting up on the left side of the FR 11 is a bus bar unit 1. The bus bar unit 1 is installed in a space between the BU shelf 2 and the ACS 19 or the SCCI 20. The bus bar unit 1 is connected to a plurality of the BU 15 included in the BU shelf 2, which is provided in the BU shelf 2, and attached by a fastener and/or an engager to a side surface of the BU shelf 2. For example, the fastener is a screw or claw etc. The bus bar unit 1 connects the outputs of the batteries to the PSU 14 of FIG. 2A and the ACS 19 in one batch and sends the control signals of the batteries to the CMU 13 of FIG. 2A, and also functions as a line for transferring various signals from the CMU 13 of FIG. 2A to other units.

The BU 15 in the storage device 100 can be an important feature. Generally, the storage devices 100 are used in an online system. Therefore, the storage device 100 must continue its operation for a certain period of time after electricity failure is occurred.

In recent years, the BU 15 is becoming more compact and the BU 15 has a plurality of signal lines. The BU 15 has high-performance. The high-performance leads to downsizing of the connectors of the BU 15 and high density cable of the connectors of the BU 15. Therefore, a bus bar unit 1 could increase the risk of accidental damages when the BU 15 connects to the bus bar unit 1. Therefore, the bus bar unit 1 needs maintenance and the replacement. But, the storage device 100 can not stop its operation by the maintenance and the replacement.

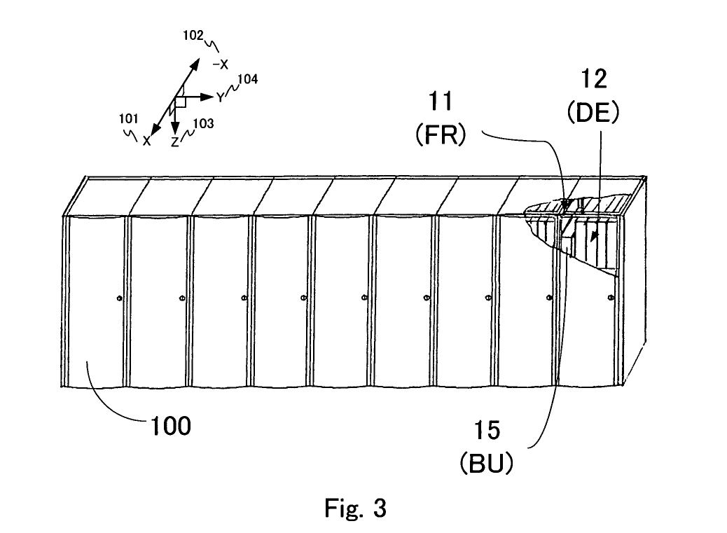

FIG. 3 illustrates a state where a plurality of the storage devices 100 according to an embodiment of the present invention. The storage devices 100 of the disk array system are arrayed so as to achieve a larger memory capacity while achieving installation within a smaller space. In this state, a maintenance and replacement processes of the unit of the storage device 100 is allowed only through the front and rear surfaces of the storage device 100. The maintenance and replacement processes are substantially not possible through the side surfaces of the storage device 100. For example, the DE 12 and the BU 15 can attach to the FR 11. And the DE 12 and the BU 15 can detach from the FR 11 through the front and rear surface (as case may be).

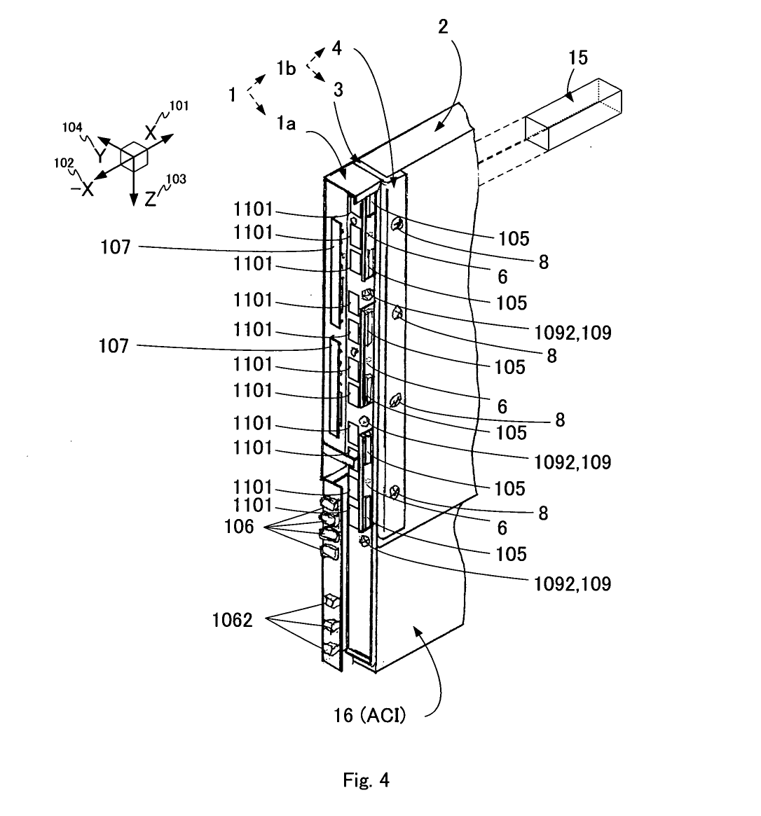

FIG. 4 shows a partial overhead view of FIG. 1 of the bus bar unit 1 and the BU shelf 2 according to an embodiment of the present invention. The bus bar unit 1 has the main body 1a and the bracket 1b. The main body 1a can support primary components such as connectors and wires. The bracket 1b functions as an attachment part, for example to the BU shelf 2 of the storage device 100. The ACI 16 is an AC-power input for the CMU 13 in FIG. 1.

The main body 1a has one or more connector(s) comprising connector 105, connector 106, connector 1062, and connector 107.

Example storage device 100 unit connected via the bus bar unit 1 is as follows: The connector 105 connects the BU 15 and the CMU 13 in FIG. 1 via a cable for transferring the control signal between each other. The cable connects the connector 107. Moreover, the connector 105 connects the ACI 16 via a cable and the BU 15. The cable connects the connector 1062. The connector 105 connects other units of the storage device 100 via the connector 106 and the BU 15. The ACI 16 provides the power to BU 15 and the other units of the storage device 100. If the ACI 16 can not supply the power, the BU 15 supplies the power to the other units of the storage device 100. The CMU 13 and the BU 15 transfer the control signal between each other. The connector 105 connects to a connector of the BU 15 via one or more openings of the BU shelf 2.

The connector 106 connects the BU 15 via the connector 105 and the PSU 14 in FIG. 2A via a cable for supplying the power. The connector 1062 connects the BU 15 via the connector 105 or the ACI 16 via a cable and other units of the device 100 for supplying the power. The connector 107 connects the BU 15 via the connector 105 and the CMU 13 via a cable for transferring the control signal.

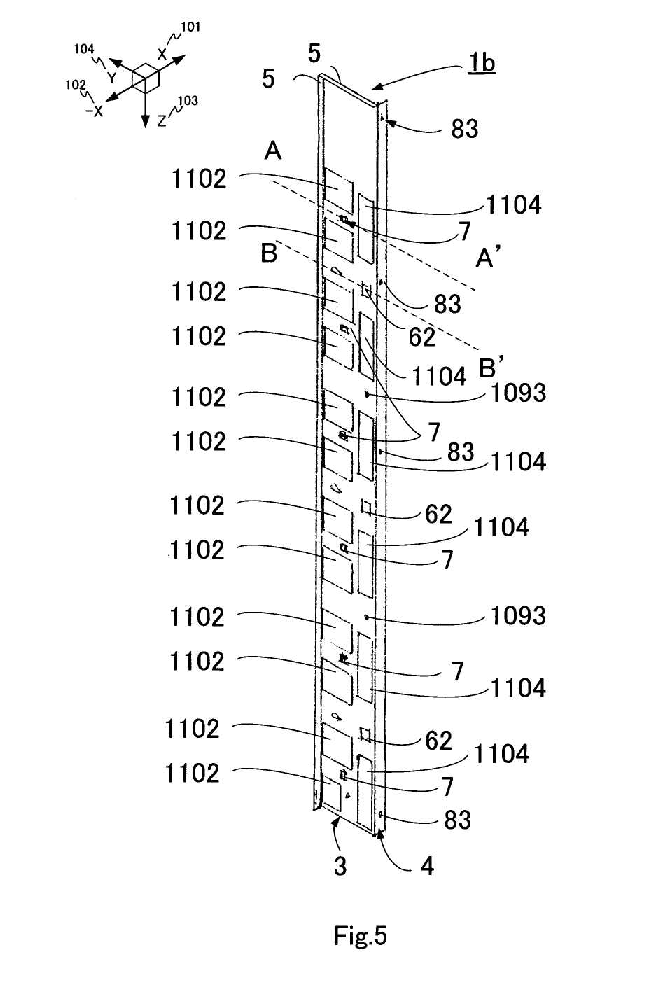

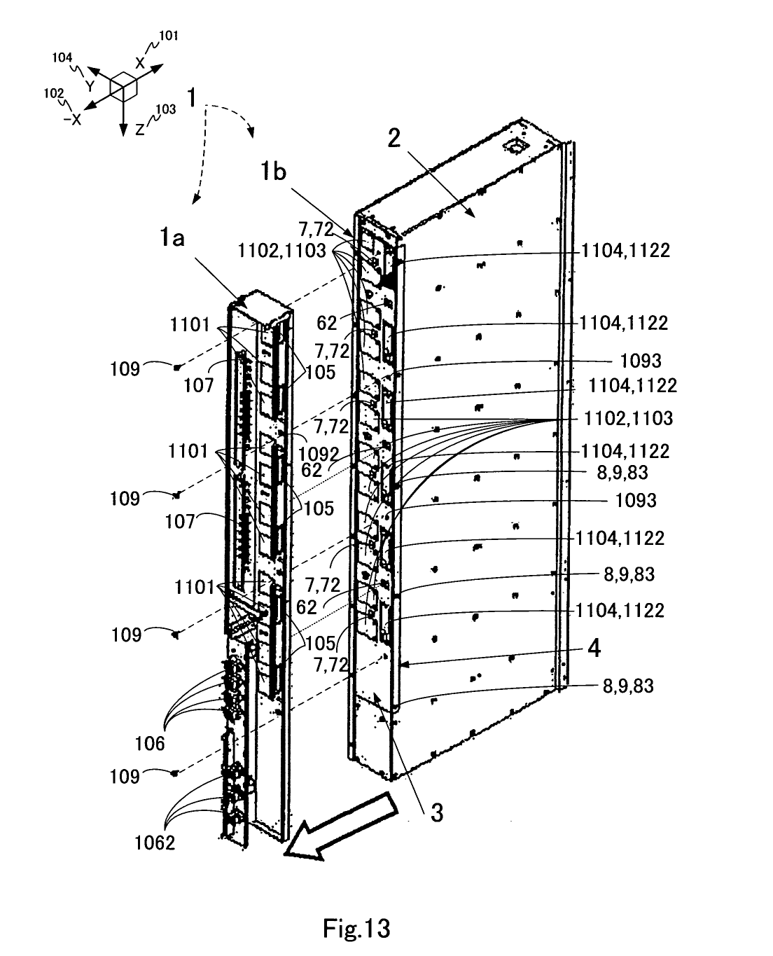

The main body 1a also has one or more an openings 1101. The openings can be function as air holes or for ventilation. The bracket 1b also has one or more air holes 1102 in FIG. 5. The BU shelf 2 has an air hole 1103 in FIG. 13. The position of the air hole 1101 in the main body 1a, the position of the air hole 1102 in the bracket 1b in FIG. 5 and the position of the air hole 1103 in the BU shelf 2 in FIG. 13 correspond to each other (i.e. overlap when assembled). Air passes through the air hole 1101, the air hole 1102 in FIG. 5, and the air hole 1103 in FIG. 13 for cooling down the BU 15.

The main body 1a has a plurality of engagers for engaging the bracket 1b. The engager is, for example, a claw and a screw. The main body 1a and the bracket 1b are engaged by a claw 6 of the main body 1a and a claw hole 62 of the bracket 1b in FIG. 5. The claw hole 62 in FIG. 5 is engaged by the claw 6. The main body 1a has a plurality of screw holes 1092. The bracket 1b has a plurality of screw holes 1093 in FIG. 5. The screw hole 1092 and the screw hole 1093 in FIG. 5 can be engaged by a plurality of screws 109.

FIG. 5 shows the bracket 1b in a partial overhead view of FIG. 4 according to an embodiment of the present invention. For example, the bracket 1b can be formed of a long steel plate that is bent substantially perpendicularly in a direction parallel to the bracket portion 1b longitudinal direction. Thus, the attachment direction of the bus bar unit 1 for an assembly process can be set differently from the detachment direction thereof for a maintenance process by a predetermined angle (in this case, about 90°).

One of bent segment of the bracket 1b serves as a main-body attachment segment 3, and the other bent segment serves as a flange segment 4. A plurality of flange segments 5 can also be provided.

The bracket 1b has a plurality of engagers for engaging the BU shelf 2. The engager is, for example, a claw 7. For example, the claw 7 is formed by punching out and bending a section of the plate. The main-body attachment segment 3 has a plurality of holes 1102 for passing air. The main-body attachment segment 3 has a plurality of holes 1104 for connecting the connector 105 of the main body 1a and the connector of the connector of the BU 15 in FIG. 4. The main-body attachment segment 3 has the claw holes 62 to engage the bracket 1b.

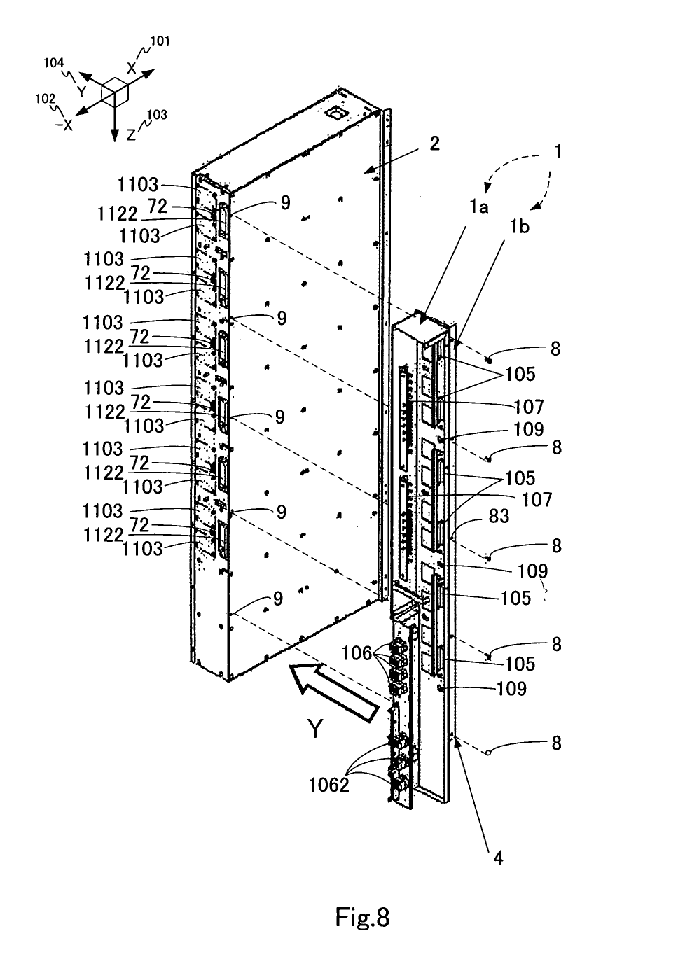

A flange segment 4 has a plurality of screw cramp holes 83. The screw cramp holes 83 and the holes 9 (FIG. 8) of the BU shelf 2 are cramped by the screw 8. A surface of the flange segment 4 is parallel to a side surface of the storage device 100. The flange segment 4 extends to attach to the BU shelf 2, and can also extend in other side of the attachment segment 3 or in other direction with respect to the attachment segment 3 to serve as guider(s) 5 to receive the bracket 1b.

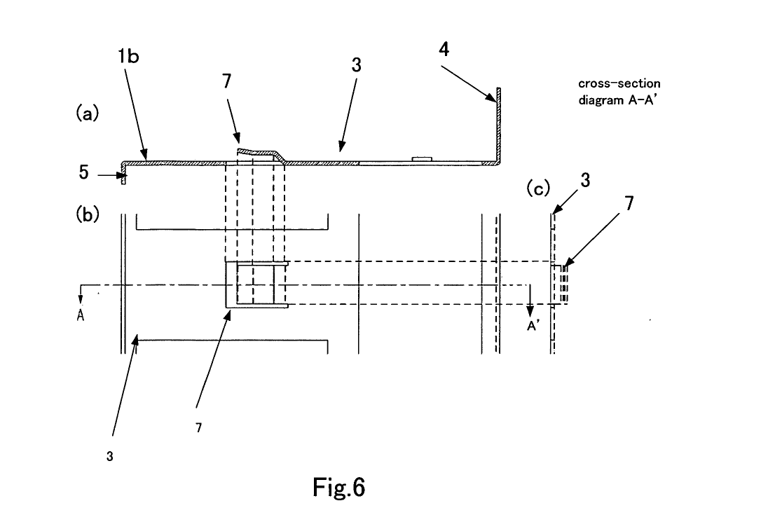

FIG. 6 shows a projected figure of the bracket 1b in three directions in FIG. 5, according to an embodiment of the present invention. In FIG. 6, (a) shows the claw 7 of the bracket 1b as viewed for the Z-direction 103. The bracket 1b has the claw 7 in the main-body attachment segment 3. The bracket 1b has the flange segment 4. In FIG. 6, (b) shows the claw 7 of the main-body attachment segment 3 as viewed for the X-direction 101 within a line A-A′ in FIG. 5. In FIG. 6, (c) shows the claw 7 of the main-body attachment segment 3 as viewed for the Y-direction 104 and shows the area corresponding to (a) in FIG. 6.

The claw 7 is formed by punching out and bending a section of the main-body attachment segment 3 of the bracket 1b. The claw 7 is provided in a surface opposite to the surface to be joined to the main body 1a. Thus, the claw 7 is engageable to a receiving hole 72 of the BU shelf 2 in FIG. 8. The bracket 1b disposes each of the claws 7 further towards the inside beyond the flange segment 4 in the storage device 100, as viewed for the Y-direction 104. A portion of the claw 7 when positioned or arranged in the storage device 100 might be difficult to access use the screws. The claw 7 provides an advantage of attachment when the bus bar unit 1 is mounted.

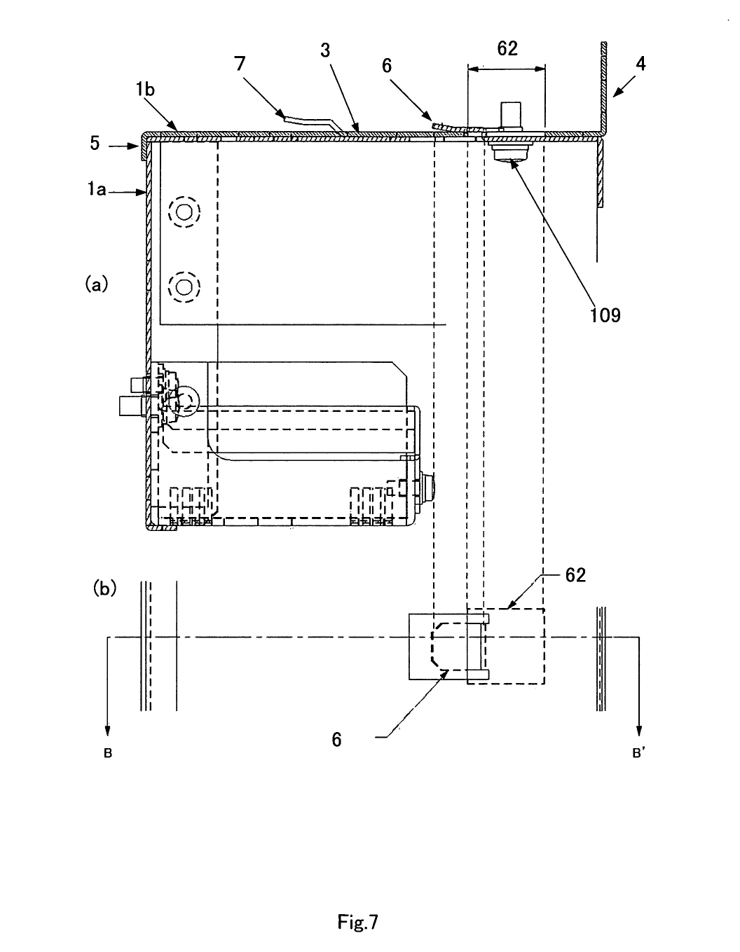

FIG. 7 shows cross-sectional views of main body 1a and bracket 1b for Z-direction 103 and X-direction 101 according to an embodiment of the present invention. These cross-sectional views are a bifacial diagram showing a state where the main-body attachment segment 3 of the bracket portion 1b is joined to the main body portion 1a. In FIG. 7, (a) is shown as viewed for the Z-direction 103, and FIG. 7, (b) is shown as viewed for the X-direction 101 taken along line B-B′ in FIG. 5.

The main-body attachment segment 3 of the bracket portion 1b and the main body portion 1a are engaged by the claw 6 and the claw hole 62. The main-body attachment segment 3 of the bracket portion 1b and the main body portion 1a are cramped by the screw 109. The flange segment 4 of the bracket 1b is explained in FIG. 5.

FIG. 8 shows an assembly figure of the position of the bus bar unit 1 which is installed in the BU shelf 2 according to an embodiment of the present invention.

An assembly process of the bus bar unit 1 to the storage device 100 has below four processes. The processes can produce the storage device 100 easy.

First process, the main body 1a and the bracket 1b are engaged to each other. For example, first the claw 6 of the main body 1a and the claw hole 62 of the bracket 1b are engaged. Second the main body 1a and the bracket 1b can be combined by screw 109.

Second process, connection cables of the bus bar unit 1 connects to connectors 105, 106, 1062, and 107 of the bus bar unit 1.

Third process, the bus bar unit 1 is attachable to the BU shelf 2 through the left side of frame 11 for the Y-direction 104 for example, through the front and/or rear of the frame 11. At the third process, the bus bar unit 1 is inserted into the space through a side surface of the frame 11. First, the claws 7 of the bus bar unit 1 (bracket 1b claw 7) in FIG. 6 and the claw holes 72 in the BU shelf 2 are engaged. Then, second the screw cramp holes 83 of the flange segment 4 and the screw hole 9 of the BU shelf 2 can be cramped by screw 8.

Fourth process, the bus bar unit 1 connects to other units of the frame 11 by the connectors 105, 106, 1062, and 107 and the cables.

Therefore, in a state where the storage device 100 is set in a field, the bus bar unit 1 can not detach through the side surfaces of the storage device 100. But the bus bar unit 1 needs maintenance or replacement under regular use. Detaching the main body 1a from the bracket 1b performs the detachment of the bus bar unit 1 when the storage device 100 is set in a field. Attaching the main body 1a to the bracket 1b performs the attachment of the bus bar unit 1 when the storage device 100 is set in a field.

The BU shelf 2 has a plurality of holes 1122. The holes 1122 are for connecting the connector 105 of the main body 1a and the connector of the BU 15. The holes 1122 overlap the holes 1104. The air holes 1103 of the BU shelf 2 are for cooling down the BU15.

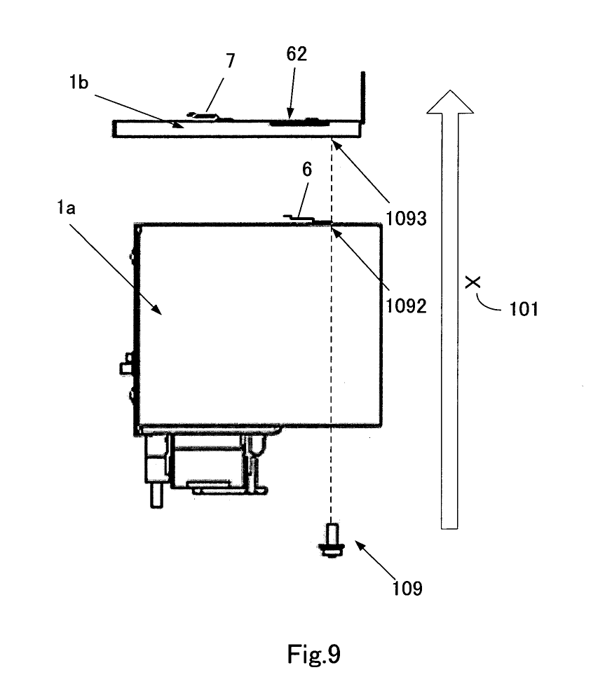

FIG. 9 shows from the upper side view of the storage device 100 when main body 1a and bracket 1b are engaging or combining according to an embodiment of the present invention. In FIG. 9, the attachment direction of the main body 1a to the bracket 1b is the X-direction 101. The screw holes 1092 of the main body 1a and the screw holes 1093 the bracket 1b are combined by screw 109. The claw 6 of the main body 1a and the claw hole 62 of the bracket 1b are engaged.

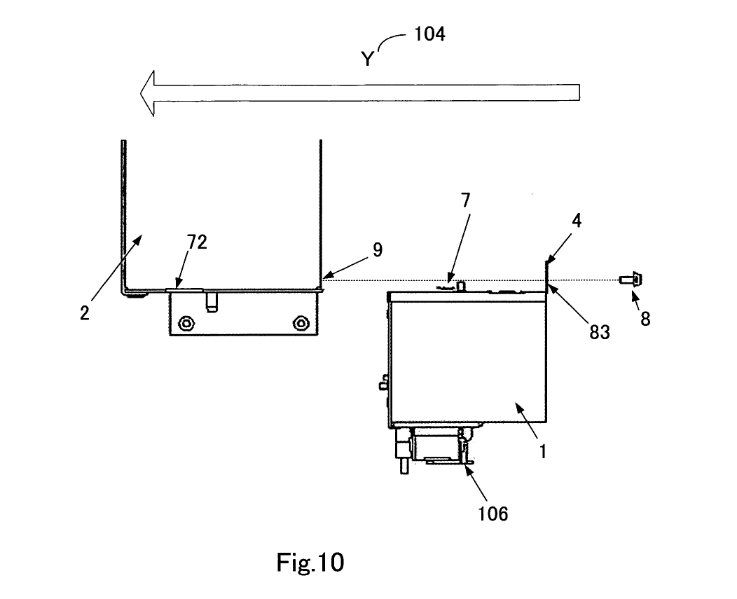

FIG. 10 shows an assembly figure from the upper side of the storage device 100 where bus bar unit 1 is installed in the BU shelf 2 according to an embodiment of the present invention. In FIG. 10, the attachment direction of the bus bar unit 1 to the BU shelf 2 is the Y-direction 104. The screw cramp holes 83 of the flange segment 4 and the screw hole 9 of the BU shelf 2 are cramped by screw 8. The claws 7 of the bus bar unit 1 and the claw holes 72 in the BU shelf 2 are engaged. The connector 106 is explained in FIG. 4.

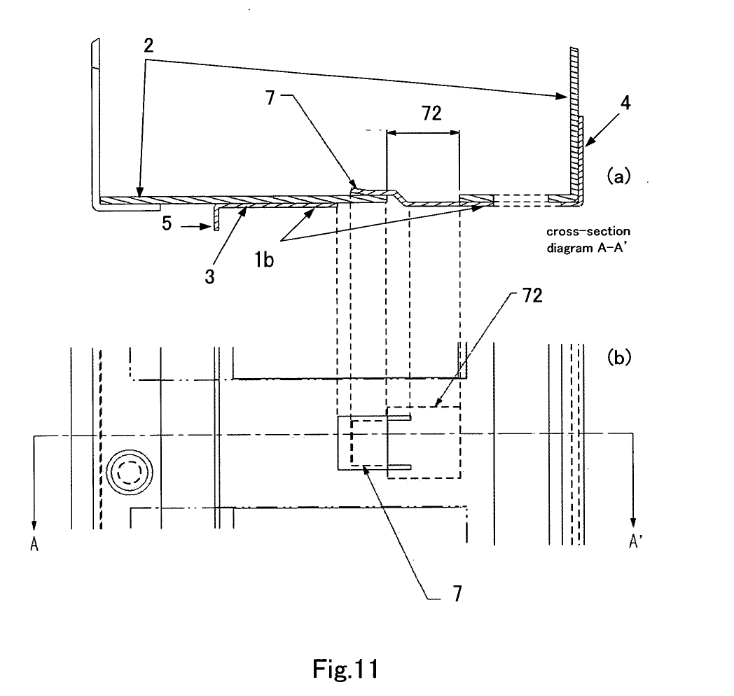

FIG. 11 shows a assembly figure from two directions where bus bar unit 1 is installed in the BU shelf 2, and correspond to the cross section taken along line A-A′ in FIG. 4. In FIG. 11 (a) is shown as viewed for the Z-direction 103. In FIG. 11 (b) is shown as viewed for the X-direction 101. The claws 7 of the main-body attachment segment 3 of the bracket 1b are engaged to the claw hole 72 of the BU shelf 2. The flange segment 4 of the bracket 1b is explained in FIG. 5.

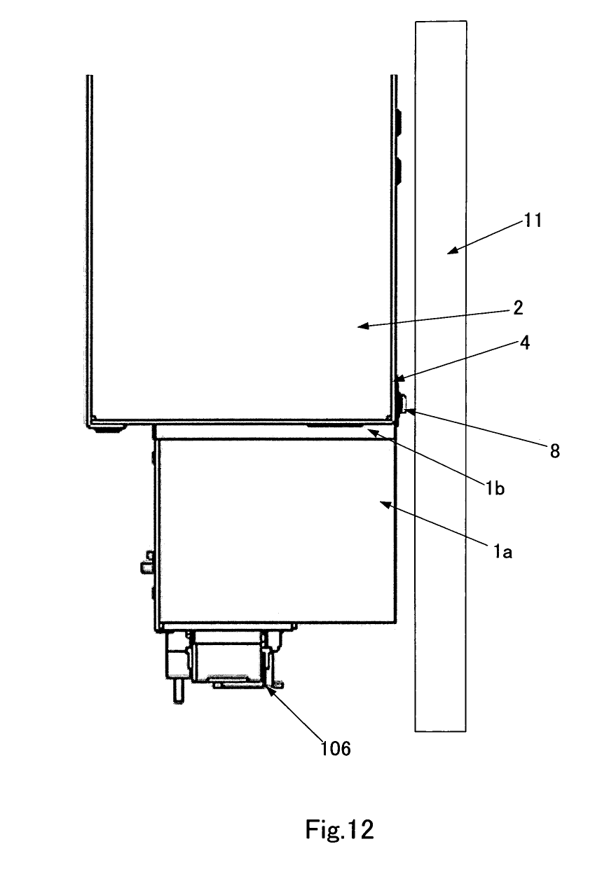

FIG. 12 shows an assembly figure from the upper side of storage device 100 where bus bar unit 1 is installed in BU shelf 2. In this state, the storage device 100 is operable.

Accordingly, the assembly process of the bus bar unit 1 is implemented within the single FR 11. Thus, the assembly process can be performed through a left side surface of the storage device 100. Furthermore, where necessary, each of the side surfaces of the storage device 100 may substantially be covered with a shielding plate so as to block electric waves between adjacent storage devices.

Each of the left surfaces and right surfaces of the storage devices 100 are joined to each other so as to form a long-wall-like structure in FIG. 3.

The flange segment 4 of the bracket 1b is explained in FIG. 5. The screw 8 is explained in FIG. 8. The connector 106 is explained in FIG. 4.

FIG. 13 shows an assembly figure from the rear side, the left side, and above where the main body 1a is detached from the bracket 1b. The detachment processes has two processes.

In first process, the ACS 19 in FIG. 1, the CN 10 in FIG. 1, and the SCCI 20 in FIG. 1 are removed from near the rear surface of the storage device 100 in FIG. 1. Since the bus bar unit 1 needs the maintenance occasionally, the complexity of such a process is permissible.

In second process, the screws 109 are detached from the screw hole 1092 of the main body 1a and the screw hole 1093 of the bracket 1b through the rear surface of the storage device 100. The claw 6 of the main body 1a is unhooked from the claw hole 62 of the bracket 1b. Thus, the main body 1a is detached in the (−X) direction 102. The (−X) direction 102 is a normal-line direction with respect to the front and rear surfaces of the storage device 100.

The bracket 1b remains on the BU shelf 2. The claw 7 of the bracket 1b and the claw hole 72 of the BU shelf 2 are engaged. And the screw cramp holes 83 of the bracket 1b and the screw holes 9 of the BU shelf 2 are cramped by the screws 8.

The air hole 1101, the air hole 1102, and the air hole 1103 are explained in FIG. 4. The air holes 1104 are explained in FIG. 5. The connector 105, 106, 1062, and 107 are explained in FIG. 4.

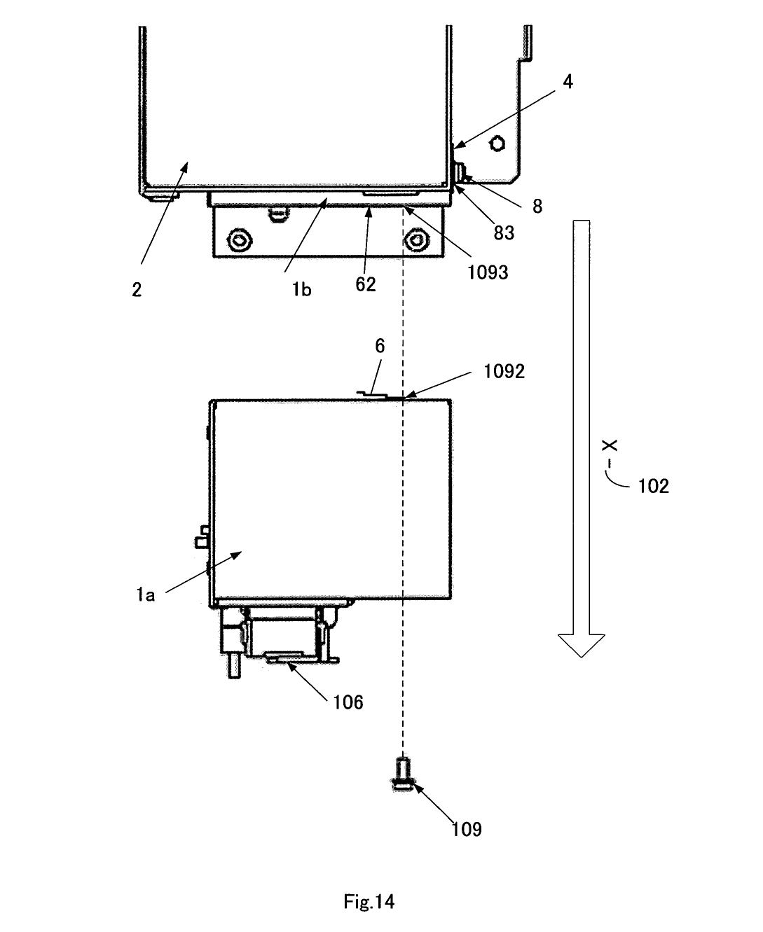

FIG. 14 shows an assembly figure from the upper side of the storage device 100 where the main body 1a is uninstalled in the bracket 1b, that is, for the (−X) direction 102 according to an embodiment of the present invention. The main body 1a can be reattached to the bracket 1b by reversing the processes in FIG. 13. Since the bracket 1b is entirely formed of a steel plate and therefore does not require maintenance, the primary object of the maintenance can be sufficiently achieved simply by detaching the main body 1a from the bracket 1b. As mentioned previously, the shape of the bracket 1b also affects the working efficiency.

The flange segment 4 of the bracket 1b is explained in FIG. 5. The screw 8 is explained in FIG. 8. The screw 109, the screw hole 1092 of the main body 1a, and the screw hole 1093 of the bracket 1b are explained in FIG. 4. The claw 6 of the main body 1a and the claw hole 62 of the bracket 1b are explained in FIG. 4. The connector 106 is explained in FIG. 4.

As described above, the embodiment of the present invention allows for maintenance and replacement processes through the front surfaces of the storage device 100 and rear surfaces of the storage device 100. Consequently, a simple assembly process is maintained. Even when a plurality of the storage devices 100 are combined to form disk array system by joining the side surfaces of a plurality of the storage devices 100, the maintenance and replacement processes for the units are permitted without pulling out a storage device 100 from an array thereof.

Consequently, without adding any excess space in the storage device 100, the maintenance and replacement capabilities for the bus bar unit 1 can substantially be achieved in an installed state of the storage device 100 while maintaining an optimal positioning of the unit 1 and optimal assembly efficiency. Furthermore, since it is completely not necessary to pull out the corresponding frame 11 from an array of the storage devices 100, the side surfaces of each of the storage devices 100 may be covered with metallic plates so as to block electric waves between the adjacent frames.

According to an aspect of the embodiments, the order in which the main body 1a, the bracket 1b, and the BU shelf 2, are engaged and disengaged is not limited to the described embodiments, and any assembly order can be provided according to type of engagers used, and according to an aspect of the embodiments any type of engagers can be used that substantially prevent movement of the bus bar unit 1 components when engaged to each other and when mounted on a unit (e.g., BU shelf 2) of a device. According to an aspect of the embodiments, the main body 1a of the bus bar unit 1 is housing having a rectangular prism shape. According to an aspect of the embodiments, the main body 1a housing has one or more side surfaces (e.g., FIG. 4) or in other words the main body 1a housing can have one or more open or exposed sides. Any connectors, for example, connector(s) 105, 106, 1062, and 107 can be mounted on any one or more of the housing side surfaces.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. An apparatus attachable to a device frame, comprising:
a housing comprising:
one or more connectors to connect with units in the device frame;
one or more engagers;
a bracket portion, comprising:
one or more first engagers engageable with the device frame;
one or more second engagers engageable with the housing engagers;
one or more openings overlap-able with the housing connectors; and,
an attachment flange attachable to the device frame.

2. The apparatus according to claim 1, wherein the engagers are claws.

3. The apparatus according to claim 1, wherein the housing is a rectangular box shape.

4. The apparatus according to claim 1, wherein the housing further comprises, a first opening, the bracket further comprises, a second opening corresponding to the housing first opening, to allow air flow to and/or from the units.
